(19) United States
(12) Patent Application Publication
(10) Pub. No.: US 2022/0215135 A1
(43) Pub. Date: Jul. 7, 2022

(54) Systems And Methods For Training Modelers In Journey-Working

(71) Applicant: Douglas Maurice Shortridge, El Cerrito, CA (US)

(72) Inventor: Douglas Maurice Shortridge, El Cerrito, CA (US)

(21) Appl. No.: 17/567,851

(22) Filed: Jan. 3, 2022

Related U.S. Application Data
(60) Provisional application No. 63/133,314, filed on Jan. 2, 2021.
(60) Provisional application No. 63/162,525, filed on Mar. 18, 2021.
(60) Provisional application No. 63/186,802, filed on May 11, 2021.

(51) Int. Cl. G06F 30/13; G06F 9/451; G09B 25/04

(52) U.S. Cl. CPC G06F 30/13; G09B 25/04; G06F 9/453

(57) ABSTRACT

A novel method for training a user of a construction modeling system includes presenting a model file to the user, receiving a request for assistance from the user, processing the request to identify training materials corresponding to the request, presenting indicia of the identified training materials to the user, receiving selection input from the user, and facilitating the modification of the model file by the user based on the presented training material. The request includes information related to a particular portion of a model file of the construction modeling system and information identifying a particular craft. The selection input indicates the selection of at least one of the training materials as a selected training material. In a particular embodiment, the method is carried out in a building information modeling (BIM) application. In another particular embodiment, the method is carried out in BIM application Add-in.

### BACKGROUND OF THE INVENTION

### Field of the Invention

This invention relates generally to construction, and more particularly to construction modeling computer applications. More specifically, the disclosed invention's field is assistance, instruction, tutoring, training, education, and best practices in application operation and modeling during use of a building information modeling application (hereinafter “BIM app”).

### Description of the Background Art

The building construction field may be broken into two primary aspects, “design” and “construction”. It is now common practice for a three-dimension (3D) virtual design computer assisted drafting (CAD) model of a building to be created prior to the beginning of actual construction. BIM apps such as Revit™ provide the capability for accurately detailed and comprehensive models of buildings. In addition to providing the on-site skilled labor with accurate 3D view plans for the project, BIM apps also support prefabrication of various assemblies or components for delivery and installation. The deliveries can be timed to correspond with the progress points of the project and the overall construction schedule. The result of the BIM approach is greater efficiency. The design and construction aspects have been merging as computer technology has become increasingly important in the building construction process. The timeline from conceptual design of the building and site infrastructure to the moment when the building is substantially complete has been relatively shortened because of the advances of BIM technology. One consequence of the realized shortened schedule is ongoing, and indeed increasing, expectation of productivity gains. This places ever greater demands upon the BIM side of the design-plus-actual-construction equation.

However, due to the wide variation of crafts, materials, supply sources, structural engineering requirements, mechanical—electrical—piping/plumbing (MEP) requirements, building sizes and shapes, climate and weatherization requirements, geographic location, type of occupancy, and other things which may impact design and construction of buildings, there is a wide spectrum of knowledge required to be applied to the model as it develops. No individual person could possibly retain all the knowledge and experience of every craft (e.g., every skilled trade) required to adequately model every portion of a building such as a hospital or a mixed-use high rise.

For BIM to be at a level of detail (e.g., LOD 400, which is a known industry standard of precision) required to accurately create prefabricated portions of journeywork subsequently installed for realized productivity gains, the modeler must know the nuances of the given craft very well. Not only is it important for dimensions and configurations to be correct, but the awareness of the field conditions in which the prefabricated assemblies are installed is key. In some crafts, there are important building code issues which must be incorporated in the modeling process. The term “constructible” is often used to describe that which is modeled virtually and ultimately is efficiently realized as a correctly constructed component of a building. This requires journeyman-level craft knowledge combined with highly accurate modeling capability.

BIM applications capable of LOD 400 modeling are complex programs and have a reputation of being difficult to learn. In addition, as with any computer program development, sometimes bugs present themselves in a way that are not apparent to a new user as being something outside their control at the time. In other words, they may not be able to recognize whether they are facing user error or program error. Finally, as with any complex and comprehensive computer application, there are limitations of functionality which a user may encounter and may struggle in search of a work-around. This can add to the frustration in learning how to efficiently use an application to model journeywork.

An application, which can be utilized to manipulate, manage, and process the data required to virtually model a complete building, must have highly variable user functionality. The wide spectrum of functionality contributes, at least in part, to the steep learning curve of adequate operation of a BIM application. All modeler users must become skilled in the most basic functions of the applications, but for different aspects of construction modeling, other functions may or may not be important to know, depending on which craft is of concern.

Although general BIM application functionality training is available, specialized craft-specific training is not so readily available. For example, one person may have experience in a craft but not in conceptual design of a building, and yet the limited training available to them may focus on functionalities which do not apply directly to modeling in their craft. Another student may be concerned about designing an adequate structural frame for the conceived building, caring little about designing a curved wall at the facade and yet the training may delve heavily into curved walls because the instructor is familiar with that area of functionality. Maybe another student has some experience in finish carpentry and hanging doors but has never used her carpentry skills to form a large concrete structural retaining wall and is left with an experience gap which prevents her from modeling the work in such an approach that prefabbed concrete form panels can efficiently be built off site and trucked to the project later for an increased productivity pay off.

Because there is no focused training widely available for craft-specific or construction situation-specific BIM app modeling, productivity and quality suffers in the overall construction industry BIM process. This conundrum has continued to plague the construction industry over the years and has essentially become an element of the modern construction sector culture. Because of this lack of craft-focused BIM app training, the skilled trades in the field often find the prefabbed work sent to them to be wrong for a variety of reasons. In many companies, it is expected that there will be substantial need for reworking or starting from scratch on any number of portions of the project, portions which were intended to be brought to the site as construction-ready prefabricated assemblies but instead became useless waste or recycle materials. As this becomes a regular, expected, and even hoped-for reality in some aspects of the field work crew culture, this work-culture dynamic further entrenches the lack of progress to greater technology-led productivity in the construction sector.

### SUMMARY

The present invention overcomes problems associated with the prior art by providing a system and method for providing training to a user of a modeling system. The training can be in the use of the modeling system itself, or the training can be apprentice type training in a selected craft (e.g., a skilled trade such as electrical, plumbing, pipe fitting, carpentry, and/or any other craft). The invention facilitates the provision of virtual training to a modeler similar to the training an apprentice would receive in the field.

Example methods for training a user of a construction modeling system are disclosed. One example method includes presenting a model file to the user and receiving a request for assistance from the user. The request can include information related to a particular portion of a model file of the construction modeling system, and the request can also include information identifying a particular craft. The example method additionally includes processing the request to identify training materials corresponding to the request and presenting indicia of the identified training materials to the user. Selection input can be received from the user. The selection input can indicate the selection of at least one of the training materials as a selected training material. The example method additionally includes retrieving the selected training material and presenting the retrieved training material to the user. The example method can also include facilitating the modification of the model file by the user based on the presented training material.

In an example method, the training materials can include an image of at least one assembly of components corresponding to the particular craft.

In an example method, the information related to the particular portion of the model file can include an assembly created by the user and corresponding to the particular craft. The information related to the particular portion of the model file can also include a second assembly of components corresponding to at least one other craft different than the particular craft. The assembly and the second assembly can being in a same portion of the model file, whereby the second assembly constrains a configuration of the assembly. For example, structural and plumbing components can constrain the configuration of electrical components in the same space. In a particular example method, the training materials can include information corresponding to at least one pre-approved assembly suitable for use in combination with the second assembly. In addition, the at least one pre-approved assembly can be representative of an actual installed assembly from a prior construction project.

In an example method, the training materials can include an instructional video related to field installation of an assembly corresponding to the particular craft. As another option, the training materials include information relating to an environmental impact of one or more components represented within the model file. Example methods can also include storing an assembly of the modified model file as a new training material.

In an example method, receiving the request for assistance from the user can include presenting the user with a choice between training in the use of the modeling system and virtual training in the particular craft.

In an example method, the particular craft can include one of carpentry, plumbing, electrical, masonry, and heating, ventilation, and air conditioning. Indeed, the particular craft can include any skilled trade, now known or even those developed in the future.

Example methods can additionally include storing a record indicative of the user's selection of the selected training material.

In particular example methods, the information related to a particular portion of a model file can include the user's selection of the particular portion of the model file and other information manually entered by the user. For example, the user can select a portion of the model file by, for example, using an input device (e.g., mouse, stylus, and so on) to create a bounding box around the particular portion of the model file. Then, the user can manually enter additional information (e.g., assembly classification, material type, craft, and/or any other useful information) by, for example, using a keyboard, selecting from a list with a pointing device, and so on.

In an example method, the training materials can include a plurality of pre-approved assemblies. Each of the pre-approved assemblies can be stored in association with a dimension value and a material type indicator. The information related to the particular portion of the model file can includes an assembly created and selected by the user in the model file and contained within a bounding box. Processing the request to identify the training materials corresponding to the request can include determining a material type of the selected assembly and determining at least one dimension of the bounding box. Then, processing the request can additionally include searching the plurality of pre-approved assemblies to identify particular ones of the pre-approved assemblies that have a material type indicator that corresponds to the material type of the selected assembly and that have a dimension value that is within a predetermined range of a dimension of the bounding box.

In a more particular example method, each of the pre-approved assemblies can be stored in association with a volume value. Then, processing the request to identify the training materials corresponding to the request can include determining a volume of the bounding box and searching the plurality of pre-approved assemblies to identify particular ones of the pre-approved assemblies with a volume value that is within a predetermined range of the volume of the bounding box.

In an example method, the processing of the request to identify training materials corresponding to the request can be location sensitive. For example, the method can include determining a geographical location corresponding to a construction site, and identifying the training materials based at least in part on the geographical location. The example method can provide training for requirements (e.g., building codes, etc.) that change based on location.

Example systems for training a user of a construction modeling system are also disclosed. An example system includes a hardware processor and memory. The hardware processor is configured to execute code. The code includes a set of predefined instructions that cause the hardware processor to perform associated operations. The memory can store data and the code. The data and the code can include a modeling service and a training service. The modeling service can include a first subset of the set of predefined instructions configured to present a model file to a user and to facilitate modification of the model file by the user. The training service can include a second subset of the set of predefined instructions. The second subset of predefined instructions can be configured to receive a request for assistance from the user. The request can include information related to a particular portion of a model file and information identifying a particular craft. The second subset of instructions can also be configured to process the request to identify training materials corresponding to the request. The second subset of instructions can also be configured to present indicia of the identified training materials to the user. The second subset of instructions can also be configured to receive selection input from the user. The selection input can indicate the selection of at least one of the training materials as a selected training material. The second subset of instructions can also be configured to retrieve the selected training material, and to present the retrieved training material to the user. The modeling service can then facilitate modification of the model file by the user based on the presented training material.

In an example system, the training materials can include an image of at least one assembly of components corresponding to the particular craft.

In an example system, the information related to the particular portion of the model file can include an assembly created by the user and corresponding to the particular craft. The information related to the particular portion of the model file can also include a second assembly of components. The second assembly of components can correspond to at least one other craft different than the particular craft. The assembly and the second assembly can be in a same portion of the model file, whereby the second assembly constrains a configuration of the assembly. The training materials can include information corresponding to at least one pre-approved assembly suitable for use in combination with the second assembly. The at least one pre-approved assembly can be representative of an actual installed assembly from a prior construction project.

In an example system, the training materials can include an instructional video related to field installation of an assembly corresponding to the particular craft. The training materials can additionally or alternatively include information relating to an environmental impact of one or more components represented within the model file. Example systems can additionally or alternatively include a third subset of the set of predefined instructions configured to store data indicative of an assembly of the modified model file as a new training material.

In an example system, receiving the request for assistance from the user can include presenting the user with a choice between training in the use of the modeling system and virtual training in the particular craft.

In an example system, the particular craft can include one of carpentry, plumbing, electrical, masonry, and heating, ventilation, and air conditioning.

In an example system, the data can include or be updated to include a record indicative of the user's selection of the selected training material.

In an example system, the information related to a particular portion of a model file can include the user's selection of the particular portion of the model file. The information related to a particular portion of a model file can also include other information manually entered by the user.

In an example system, the training materials can include a plurality of pre-approved assemblies. Each of the pre-approved assemblies can be stored in association with a dimension value and a material type indicator. The information related to the particular portion of the model file can include an assembly created and selected by the user in the model file and contained within a bounding box. Processing the request to identify the training materials corresponding to the request can include determining a material type of the selected assembly and determining at least one dimension of the bounding box. Then, processing the request can additionally include searching the plurality of pre-approved assemblies to identify particular ones of the pre-approved assemblies that have a material type indicator that corresponds to the material type of the selected assembly and that have a dimension value that is within a predetermined range of a dimension of the bounding box. Each of the pre-approved assemblies can additionally or alternatively be stored in association with a volume value. Processing the request to identify the training materials corresponding to the request can then include determining a volume of the bounding box and searching the plurality of pre-approved assemblies to identify particular ones of the pre-approved assemblies with a volume value that is within a predetermined range of the volume of the bounding box.

In an example system, the provision of training materials can be location sensitive. For example, processing of the request to identify training materials corresponding to the request can include determining a geographical location corresponding to a construction site and identifying the training materials based at least in part on the geographical location.

Systems can be configured to implement any of the methods or any combination of the methods disclosed herein. Similarly, any of the methods or combination of methods disclosed herein can be implemented using any type of electronically readable medium having code embodied therein that, when executed, will cause an electronic device to perform the disclosed method or methods.

In one embodiment, the present invention is an add-in to a BIM application such as, for example, Revit™ which can provide craft-specific pertinent assistance, instruction, tutoring, training, education, technique, and/or best practices information regarding the BIM application functionality and operation, as well as construction methods, approaches, manners, techniques, materials, practices, examples, and other targeted support information pertinent to the craft-specific modeling situation, all while using the BIM application. It is a system and method to assist a BIM modeler/detailer in the requisite knowledge of a craft or work type discipline such that the modeled work adequately represents journeywork in a real-world installation configuration, in accordance with LOD 400 industry standards of detail for constructability and applicable building codes, and best practices of a journeyman—also known as a “journeyworker” in that craft field.

The disclosed invention assists the development of knowledge about correct configuration and standard practices of the joined elements of a given building component or set of components. One goal in utilizing this aspect of the invention is for the modeler to learn the subject craft well enough that he or she reaches adequate journeyworker level knowledge and understanding and thus becomes a “virtual journeyworker”. The result is that the modeler creates “virtual journeywork”, which, when prefabricated precisely as modeled, is then installable in the field without modification (e.g., is “constructible”). This results in physical construction in compliance with the overall engineered design and specifications, in accordance with building code(s) and comporting with the construction situation at hand—yet does not require full knowledge of the traditional aspects of the craftwork by the installer nor does it require the modeler to have any actual field experience.

For purposes of this disclosure, a “virtual journeyworker” refers in part to a person who can accurately interpret architectural and engineered plans as these relate to the system of concern in the given construction field craft or discipline. Additionally, he or she has general understanding of “layout” and “coordination” (with other crafts, trades, or disciplines) as well as the labor practices, materials, tools, and equipment needed to build and test the system of concern as if on a real-world construction project.

This level of journeyworker skill attained by the modeler does not concern nor require, practicing the physical work and techniques, operating or working alongside heavy equipment, understanding and practicing the proper use of hand and power tools, jobsite safety protocols, labor force management, cooperation and coordination with field coworkers and field-oriented instructors, and other actual field and classroom conditions in which an actual journeyworker must be well versed in order to most effectively work in the field.

Much of any component, or set of components, in many models of a given craft are routine and simple requiring little training. For example, it's obvious that for a gravity drainage system to work, there must be slope in the direction of flow. Additionally, some modeling may comprise a substantial redundancy of effort throughout the modeling project. For instance, a restroom with multiple lavatories such as in an airport or convention hall, or interior non-rated walls, rated walls, rated or non-rated doors, stairways, straight single pipe or conduit runs, risers or stacks, long trapeze runs with multiple parallel MEP systems. All these entail work most any modeler/detailer familiar with the BIM app may accomplish without too much concern or question once they are given some initial instruction by the supervising architect, engineer, or BIM lead.

It is the lack of broad understanding of a given craft, and different code intricacies sometimes associated with a given construction situation, which may lead to problems caused by the uneducated modeler/detailer, in other words, a modeler who is not a “virtual journeyworker” in the craft. The present invention offers a “first line solution” to questions which otherwise may require the time and energy of a supervisor or coworker with journeyworker experience in the given situation. Reducing the cost of this traditional approach is one goal of the present invention.

Possible candidates for use of the present invention features include, but are not limited to; architects, assistant architects, structural engineers, mechanical engineers, electrical engineers, interns, students, DfMA modular housing and buildings manufacturers, journeyworker and apprentice level modelers of the MEP crafts including plumbing, mechanical and process pipefitting, fire protection, high and low voltage electrical, and sheet metal HVAC, carpenters, glazers, ironworkers, and other journeyworker level field personnel who desire a lateral transfer to the BIM department, or field-personnel increasing job engagement in the overall process of “BIM-to-Field” and “Field-to-BIM” teamwork. Closely associated or crossover craft modelers such as, for example, pipefitters/steamfitter BIM modelers who also must also model the plumbing segment of the project, is another category of potential users. Finally, building officials or quality control inspectors reviewing and marking up for project approval and/or subsequent pre- and post-inspection tracking and understanding, may utilize the disclosed invention productively.

Example systems and methods are disclosed herein. However, it should be understood the spectrum of essential functionality of the invention may vary from minimally adequate to serve its intended purpose to maximally refined and developed with unlimited potential for further refinement. It should also be understood other programming architectures, organized in such a way as to accomplish the same intended general result, are possible and would, therefore, be other embodiments of the present invention. It should be further understood that the present invention may be utilized on a stand-alone computer, on a private server network, through a virtual private network (VPN), on a virtual desktop infrastructure (VDI), on a desktop as a service (DaaS) system, supported by software as a service (SaaS), or any combination thereof, and any other combined hardware and software configuration and/or system which may be useful to the administrator and modeler situation contemplated in this disclosure.

One disclosed example embodiment of the invention is based on the plumbing craft, because the craft has a wide variation and complexity of systems, materials, installation practices, and plumbing codes. Because of the programmatic architecture required to handle the complexity of the plumbing craft, the disclosed invention is considered comprehensive as to capacity and general methods for any craft or construction required to be incorporated in BIM. It is understood that all work type disciplines required in the construction field may be substituted and/or combined into the application and, by default, will be supported with adequate processing capacity and variation.

### BRIEF DESCRIPTION OF THE DRAWINGS

The present invention is described with reference to the following drawings, wherein like reference numbers denote substantially similar elements:

FIG. 1 is a block diagram of a system for training construction modelers;

FIG. 2A represents a modeler user interface (UI) at first activation and subsequent uses;

FIG. 2B represents the modeler UI views when the “journeywork” option is selected;

FIG. 2C represents the continuation of the “journeywork” sequence, including the tutorial options;

FIG. 2D represents the UI when a BIM App tutorial option is selected;

FIG. 3 is a flow chart summarizing an example method for providing training to a modeler;

FIG. 4 is a block diagram illustrating a portion of the example system of FIG. 1;

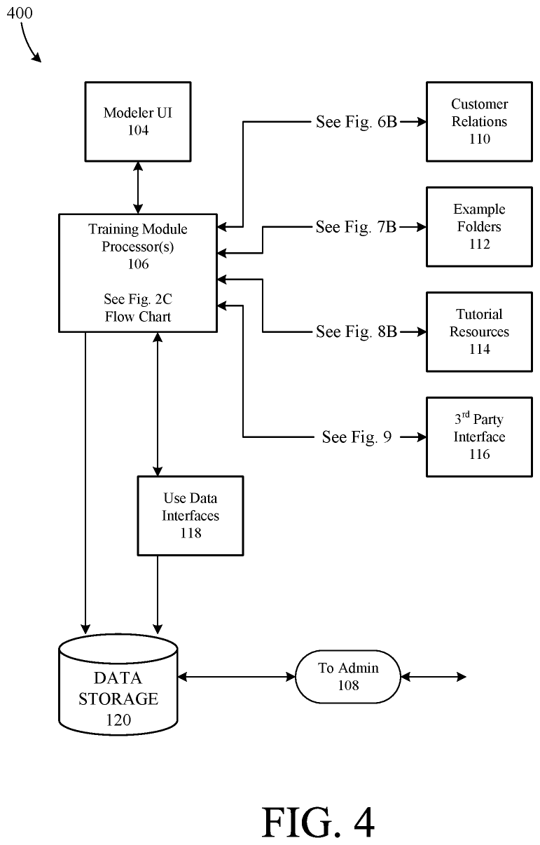

FIG. 5 is a block diagram and flow chart illustrating the operation of an Admin Module of FIG. 1;

FIG. 6A is a flow chart illustrating example configuration and/or operation of an admin-side customer relations module of FIG. 1;

FIG. 6B is a flow chart illustrating example user-side interface with a customer relations module of FIG. 1;

FIG. 7A is a chart illustrating Example Folders 112 of FIG. 1 and an admin-side Example Folders interface;

FIG. 7B is a chart illustrating user-side interaction with Example Folders 112 of FIG. 1;

FIG. 8A is a chart illustrating admin-side interaction with Tutorial Resources 114 of FIG. 1;

FIG. 8B is a chart illustrating user-side interaction with Tutorial Resources 114 of FIG. 1;

FIG. 9 is a block diagram illustrating an example 3^{rd} Party Interface of FIG. 1;

FIG. 10 is a block diagram illustrating a Use Data Interface 118 of FIG. 1; and

FIG. 11 is a block diagram illustrating Data Storage 120 of FIG. 1.

### DETAILED DESCRIPTION

The present invention overcomes the problems associated with the prior art, by providing systems and methods for training modelers in journey-working. In the following description, numerous specific details are set forth (e.g., processors, data storage, system architecture, etc.) in order to provide a thorough understanding of the invention. Those skilled in the art will recognize, however, that the invention may be practiced apart from these specific details. In other instances, details of well-known computer practices (e.g., database organization, application program interfacing, and so on) and components have been omitted, so as not to unnecessarily obscure the present invention.

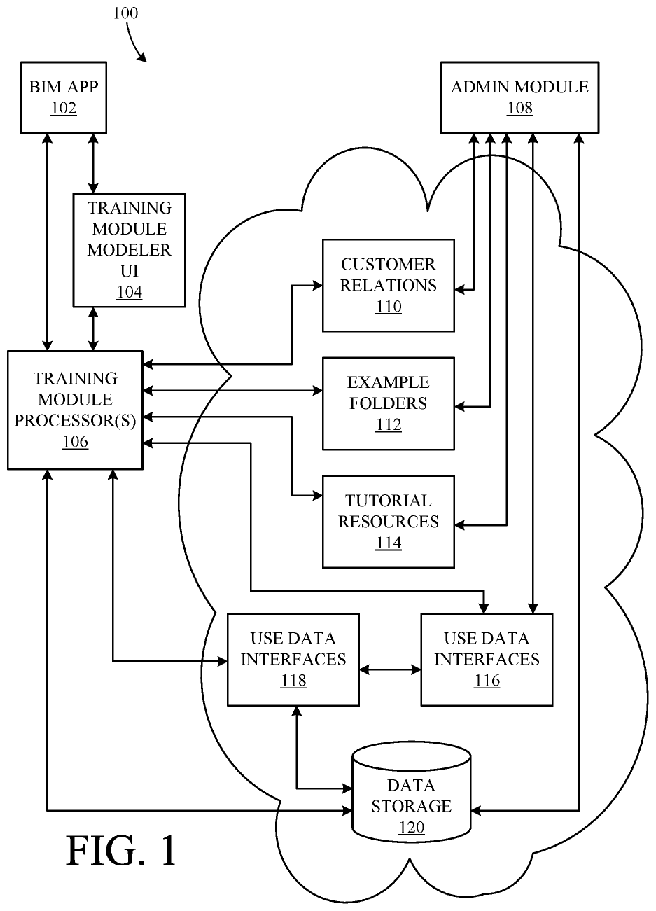

FIG. 1 is a block diagram of an example system 100 for training construction modelers. In this example, the cloud portion of the overall system is not meant to imply other configurations of local and/or cloud-based systems are not possible. For example, it is possible for the whole system to be locally hosted in a single organization. Alternately, it's possible for the whole system to be based on a virtual desktop infrastructure (VDI) or Desktop as a Service (DaaS) basis. Indeed, the components of the system can be distributed in any convenient way across one or more machines, systems, and/or networks (LAN, WAN, and so on).

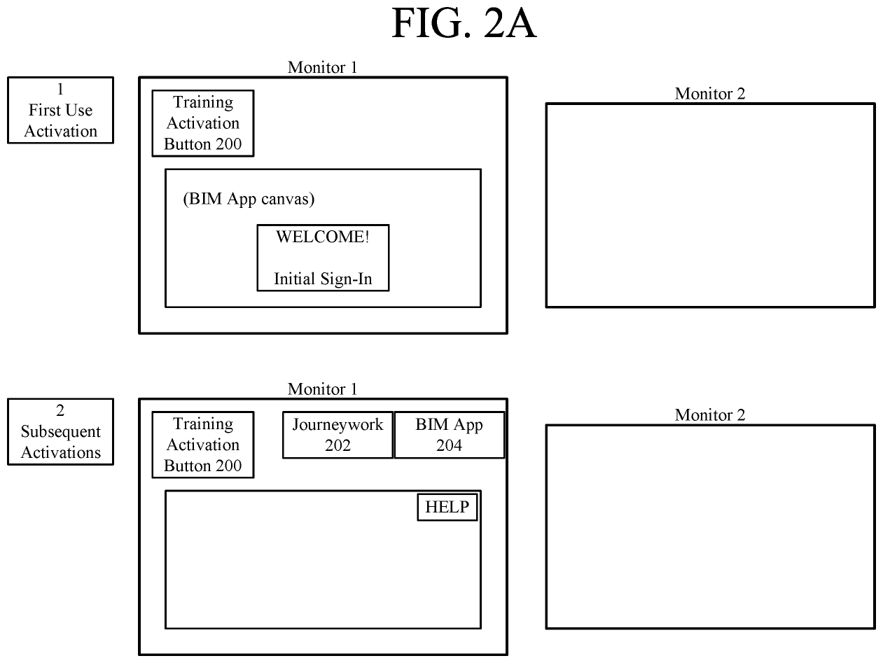

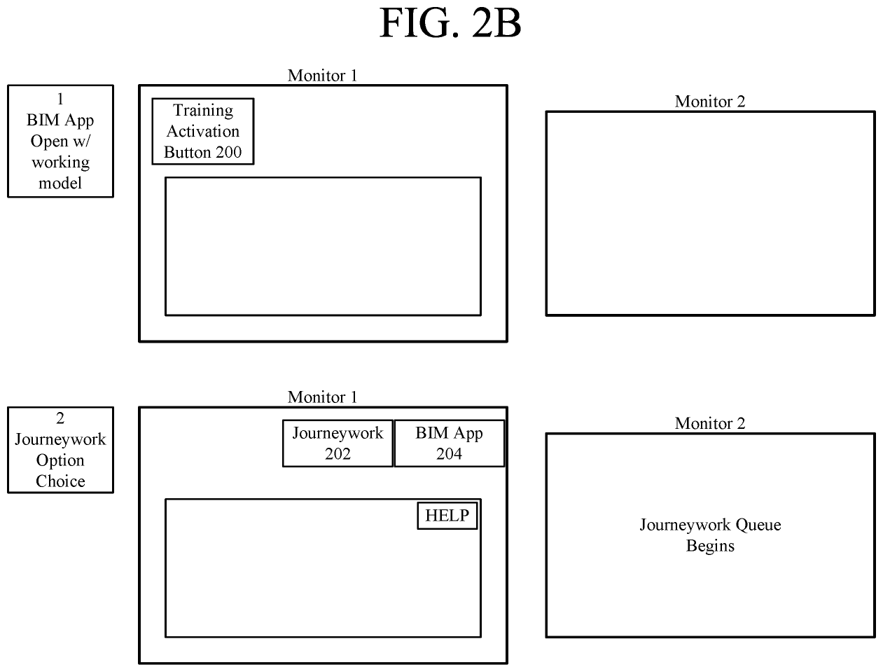

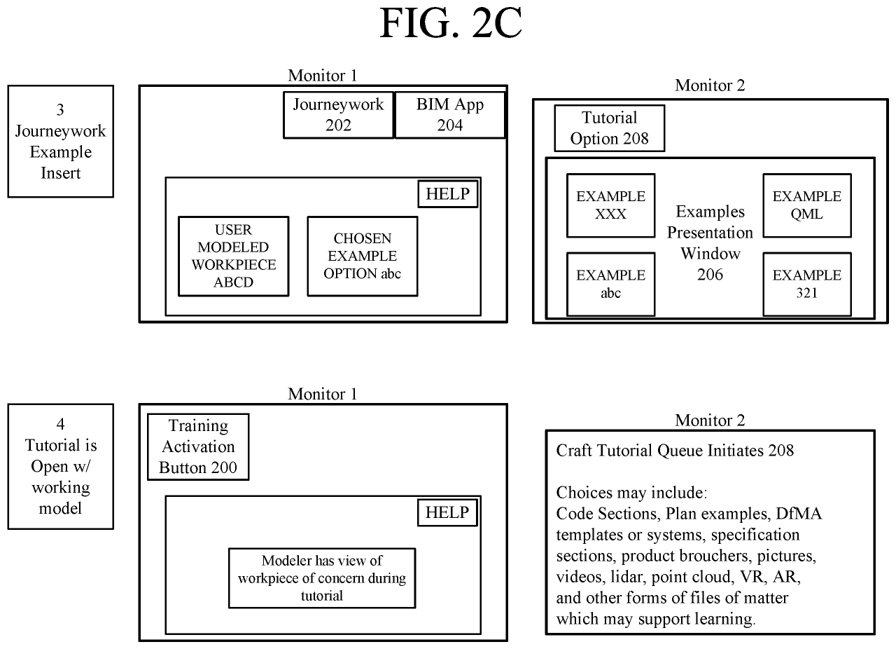

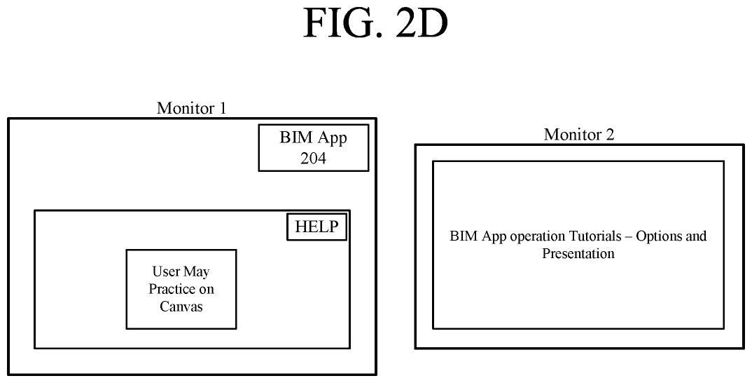

System 100 includes a building information modeling application (BIM App) 102, a training module 104, one or more processor(s) 106, an administration module 108, a customer relations 110, example folders 112, tutorial resources 114, a third party interface 116, a use data interface 118, and data storage 120. BIM App 102 is, by way of non-limiting example, a modeler end-user BIM App such as Revit™. Training module 104 is, in this example, an add-in application relative to BIM App 102. However, it should be understood that any functionality described with respect to training module 104, or any other modules of system 100, could be integrated within BIM App 102. (FIGS. 2A, 2B, and Flowchart FIG. 2C).

Processor(s) 106 represent(s) the main workstation processing of the Training Module. In this example, both BIM App 102 and training module 104 run on processor(s) 106. However, BIM App 102 and training module 104 could run on separate processors. For example, BIM App 102 can run on a local workstation processor (local to the modeler), and the training application program 104 can run on a remote cloud server in a software as a service (SAS) configuration.

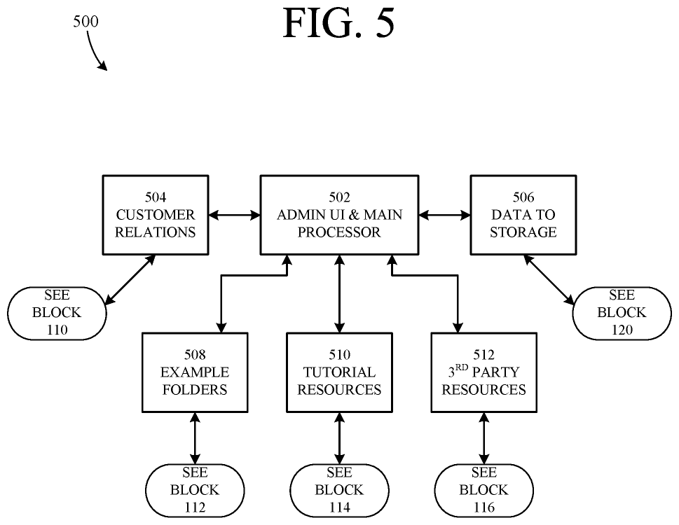

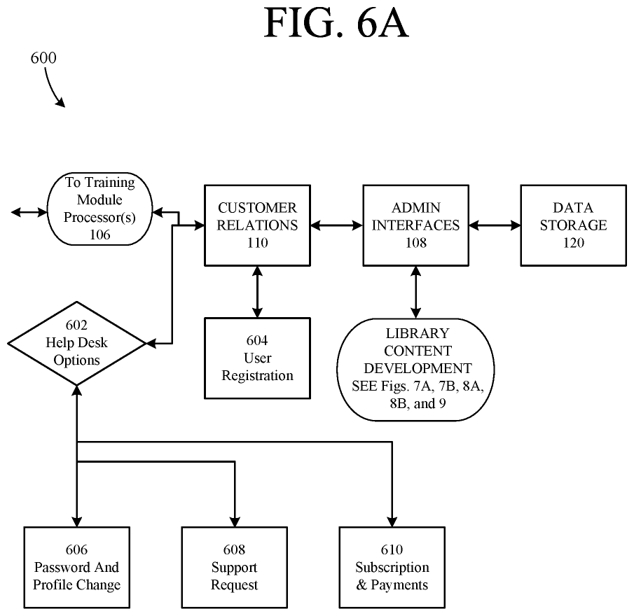

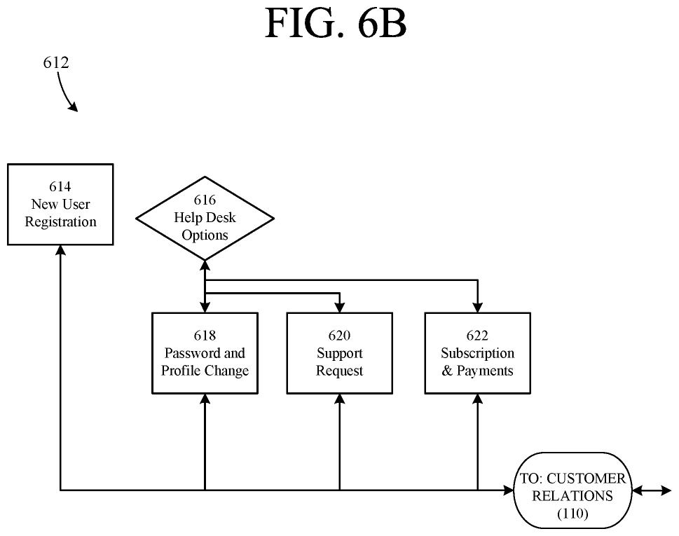

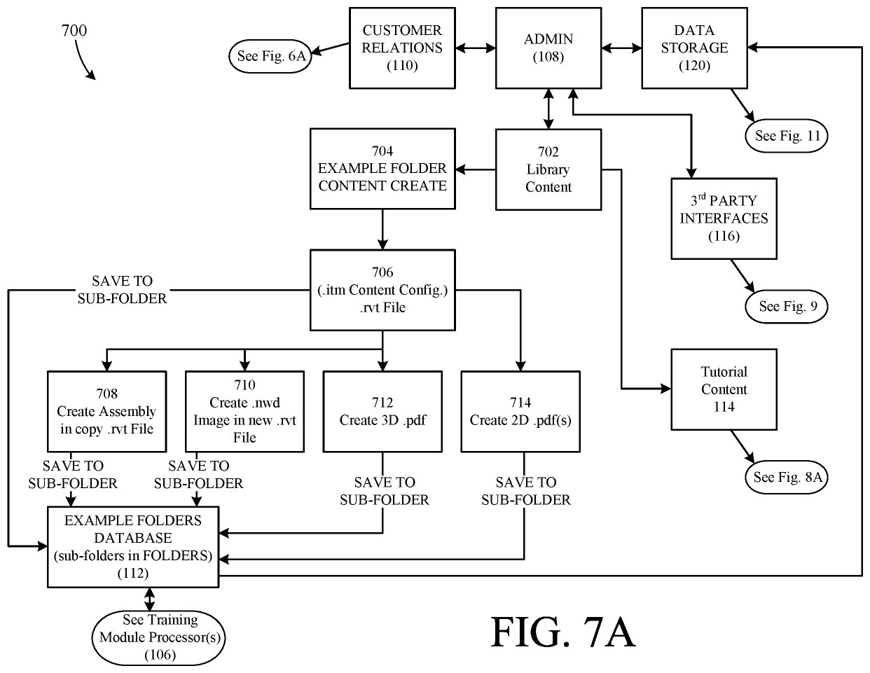

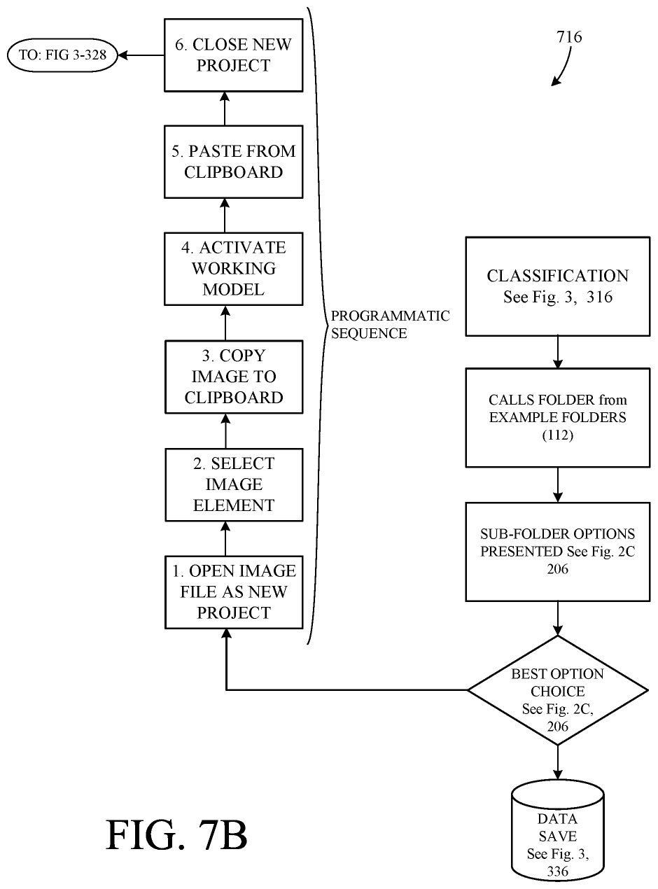

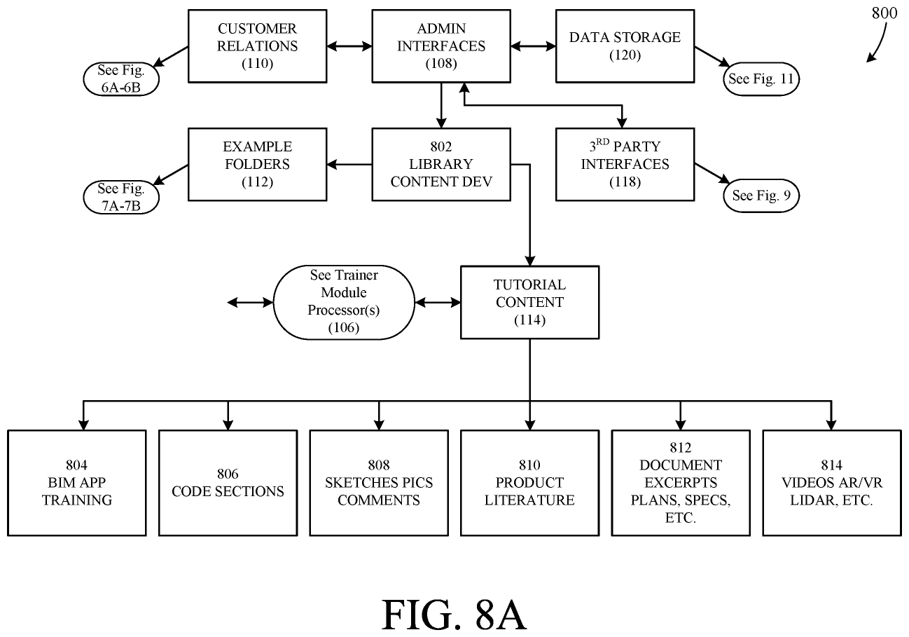

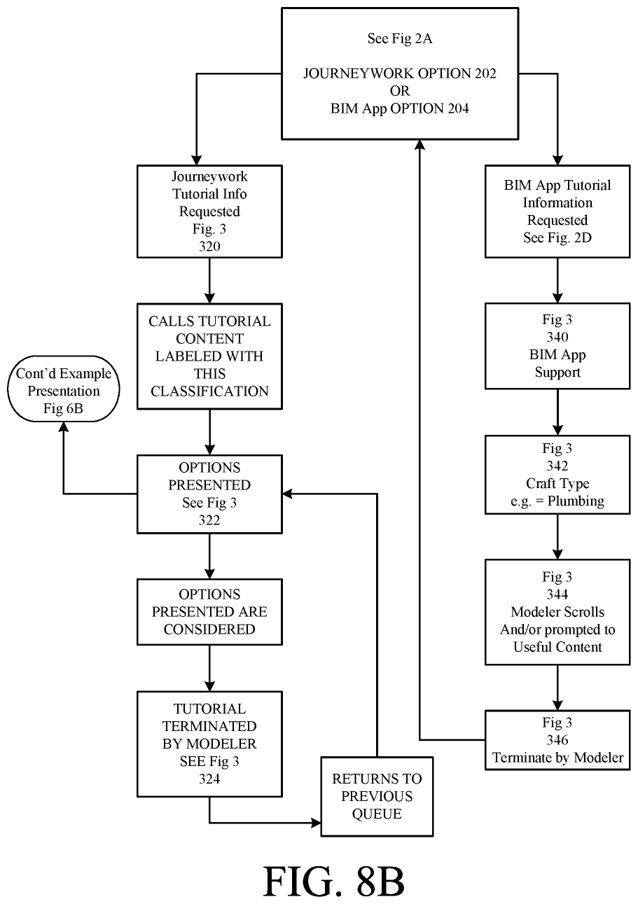

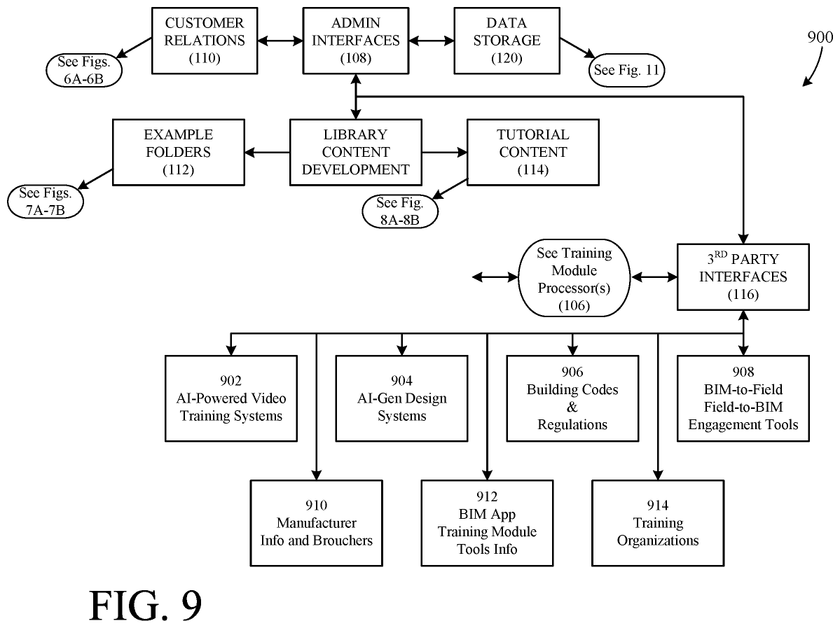

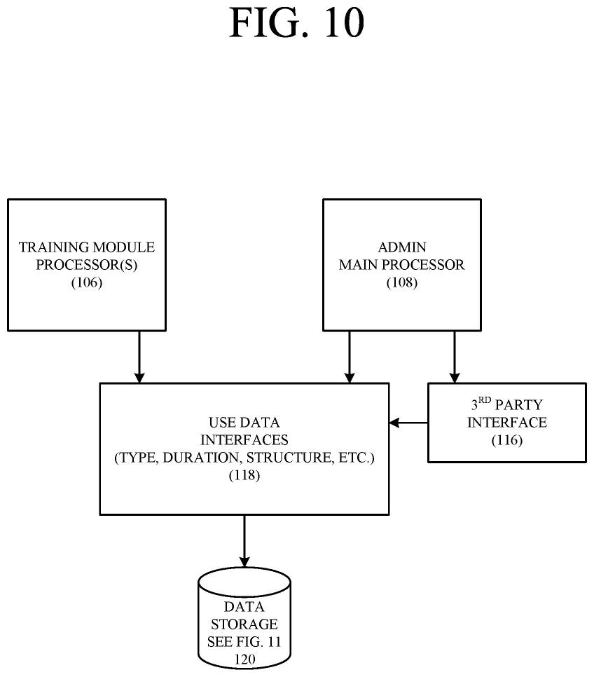

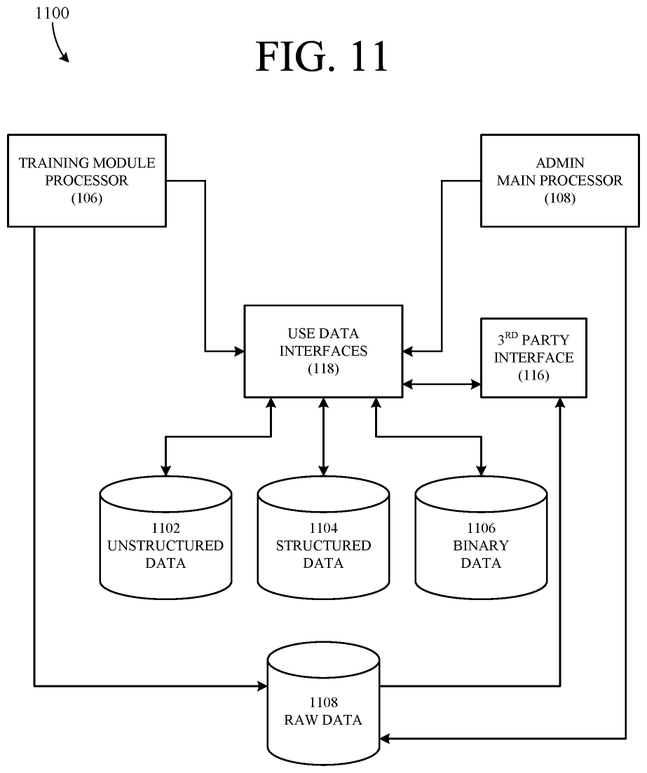

Admin module 108 represents the training system “back end” admin interfaces and workstation(s). (FIGS. 5, 6A, 7A, and 8A). Customer relations 110 handles any desired customer relations tasks such as user log-in ID, subscription services, and helpdesk support. (See FIGS. 6A and 6B). Example folders 112 represents a library of example folders, containing curated files produced, received, classified, and called. For example, each folder can include information (e.g., model files, image files, related data, and so on) related to a pre-approved assembly, such as might have been actually installed in a prior project. (FIGS. 7A and 7B). Tutorial resources 114 includes various online (e.g., hyperlinks to) and locally stored tutorial resources. (FIGS. 8A and 8B). Third-Party interface 116 provides one or more interfaces between system 100 and third party resources for outsourced, or partially outsourced, processes and services. (FIG. 9). Use data interface 118 represents the use data capture interfaces between the components of system 100 and data storage 120. (FIG. 10). Data storage 120 represents the data storage for system 100, which may be local, remote, and/or distributed across multiple locations. (FIG. 11)

FIG. 2A illustrates an example of the modeler graphical user interface (GUI) at a first activation (1) and a subsequent second activation (2). As shown in this example, monitor 1 displays a training activation button 200 during first use activation (1). During Subsequent Activations (2), whenever activation button 200 is selected, monitor 1 additionally displays a journeywork 202 button and a BIM App button 204.

FIG. 2B illustrates the modeler UI views when the “journeywork” option is chosen. When BIM App is open with working model (1), monitor 1 displays a Training Activation Button 200. When Journeywork Option Choice (2) is chosen, monitor 1 displays a journeywork 202 button, a BIM App button 204, and a HELP button while Monitor 2 displays “Journeywork Queue Begins”.

FIG. 2C illustrates the modeler UI views during the continuation of the “journeywork” sequence, including the tutorial options. At Journeywork Example Insert (3), Monitor 2 displays an Example Presentation Window 206 and a Tutorial Option 208 button. Example presentation window 206 displays examples of pre-approved assemblies that are identified by the system based at least in part on the user modeled workpiece/assembly displayed on Monitor 1.

FIG. 2D illustrates the example UI when the BIM App tutorial option is selected. As shown, Monitor 1 displays a BIM App button 204, a “User May Practice on Canvas” display, and a help button, while Monitor 2 displays BIM App operation Tutorials, Options, and Presentation.

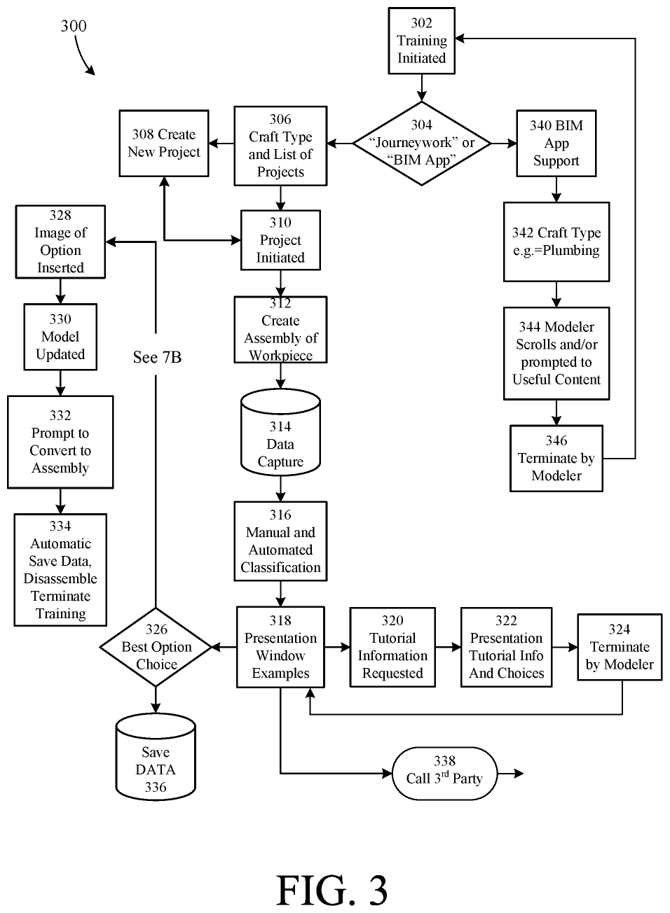

FIG. 3 is a flow chart 300 summarizing an example method 300, which may be facilitated by Training Module 104 or other components of the example system 100. Method 300 begins in a first step 302, where training is initiated. Next, in a second step 304, it is determined whether “Journeywork” training or “BIM App” training is requested. If “Journeywork” is selected, then in a third step 306 “Craft Type and List of Projects” are determined/assembled. Then, whether an existing project selected or a new project is created in a fourth step 308, in a fifth step 310 the selected or new project is initiated. Next, in a sixth step 312, the modeler creates an assembly that represents the “best effort” of the modeler. Then, in a seventh step 314, data is captured from the “best effort” assembly and, optionally, by manual entry by the modeler. Next, in an eighth step 316, the captured and/or manually input data is used to identify one or more pre-approved assemblies, which in a ninth step 318 are presented to the modeler.

In a tenth step 320 it is determined whether the modeler has requested related tutorial information and, if so, then in an eleventh step 322 any selected tutorial and/or other training information (e.g., videos, code sections, and so on) are presented to the modeler. Next, in a twelfth step 324, after all selected tutorial materials are presented, the tutorial assistance is terminated by the modeler, and method 300 returns to ninth step 318.

After completion of the requested tutorial information, then in a thirteenth step 326, one of the preapproved assemblies identified in eighth step 316 is selected as a “best choice”. Then, in a fourteenth step 328an image of the best option is provided, and in a fifteenth step 330 the model file is updated based on the selected best choice. Next, in a sixteenth step 332 the “best choice” is converted to an assembly, and in a seventeenth step 334 all (or at least some) of the data is saved and the training terminates.

Optionally, when a best option is selected in thirteenth step 326, then in an eighteenth step 336 data indicative of the “best choice” selection can be saved. As another option, if tutorial assistance is requested in ninth step 318, then in a nineteenth step 338 tutorial information can be requested/obtained from a third party.

If, in second step 304, “BIM App” training is requested, then in a twentieth step 340 BIM App support is initiated, and in a twenty-first step 342 a particular craft type is determined. Next, in a twenty-second step 344 BIM App assistance is provided to the modeler based at least in part on the determined craft type (e.g., plumbing, electrical, HVAC, pipe fitting, masonry, carpentry, and so on.), and then in a twenty-third step 346 BIM App assistance is terminated.

### The Front End

The following embodiment relates to a plumbing system portion of a building model. In this example, AutoCad Fabrication™.itm plumbing content is utilized in the Revit™ BIM App. Other types of plumbing content (or other craft content or building geometry), such as generic Revit™.rfa type may be substituted with required properties and processing modifications accomplished in an administrative domain 108 of FIG. 1. It is understood that functionalities described herein are not meant to limit the scope of the invention but are only examples portrayed for the sake of understanding the disclosed invention.

A modeler utilizing a BIM App 102 of FIG. 1 opens a “working model” project and begins to utilize the present invention for the first time by clicking a button 200 on the UI tool bar (shown in FIG. 2A). The modeler's initial sign-in profile is prompted for input as shown in step 614 of FIG. 6B, and the modeler's Training Module account is established. In the initial registration completion window a welcome message appears and prompts the user to continue. This welcome window is bypassed for all future sign-ins by the registered user. Regularly appearing in most, if not all windows, a “help desk” option 616 of FIG. 6B, appears from which the user may access help for various things such as subscription (Subscription and Payments 622 of FIG. 6B), password reset (Password and Profile Change 618 of FIG. 6B), and helpdesk (Support Request 620 of FIG. 6B). The modeler is automatically logged in to the normal operation of the Training Module until the BIM app session is ended. Subsequent modeler initiations of the BIM App automatically trigger modeler log-in for the Training Module.

Initially, the modeler is presented with two choices “Journeywork” 202 of FIG. 2A or “BIM-App Tutorials” 204 of FIG. 2B. When “Journeywork” 202 is selected, a “craft type” and a list of projects (if there yet be any) are presented in a sub-window (step 306 of FIG. 3) along with a “new project” option button (step 308 of FIG. 3).

Upon clicking “new project”, a project information window is presented for entry of project file name ID and its geographic location (for automatic building code determination or other things which may imply geographic import) and type of construction (e.g., hospital). (step 310 of FIG. 3)

Upon refresh of the Training Module, the added project will appear on the list. When additional projects are actively modeled, the “new project” window is similarly initiated each time. Once a project is added, the Training Module automatically points to the project when it is active, and the “new project” button is inactivated. Once a project is no longer being modeled, i.e. is complete or otherwise no longer being considered for changes by the modeler, it may be archived and removed from the Training Module active database and list to avoid UI clutter.

During active work on a model previously paired with the Training Module, the Training Module is in a background inactive state. When a specific area is in question by the modeler, the Training Module may be activated. The “Journeywork” button 202 is clicked. An option to switch to “BIM App Tutorial” support, is also presented if the concern has to do with the placement of elements or other app-user skills.

As the journeywork sequence begins, the first instruction presented, in step 312 of FIG. 3, is for the modeler to create an assembly of the modeled workpiece, or otherwise define the scope of the questionable workpiece by selecting the individual elements of the configuration. In step 314, any available data associated with the configuration elements can be captured for possible immediate or future use. Captured and stored data includes, but is not limited to, connections, coordinates, system type(s), material type(s), slope(s), and size(s).

The following is another example of how the data from the “best effort” assembly can be captured. A bounding box in X, Y, Z coordinates can be defined to encompass the “best effort assembly.” The bounding box's dimensions can be captured, and the volume of the bounding box determined from the captured dimensions. Data representing the material of the assembly can also be determined. Additional data associated with the “best effort” assembly can also be entered by the modeler. Any or all of the data types (dimensions, volume, material type, and/or other manually entered data types) can be used in the classification labels of the example model files. Then, given an adjustable tolerance, the example files can be searched to find example models whose data corresponds to the “best effort” data within a given tolerance.

The stored data from this user may possibly be combined with other previously stored data of like elements, and configurations of elements, whether created on the front or back ends at any previous time by at least one other modeler or administrator. Any or all this data may be employed, among other things, to automatically populate at least one aspect or increment of the classification for the subject assembly or configuration of elements currently under consideration in the model.

However, there is no requirement for data to be stored at all, let alone employed for automatic classification of like elements or any other function. Manual classification data entry may be employed in whole or in part in step 316 of FIG. 3. Further, if a lack of stored data from which to adequately support automatic classification is the case, manual classification of all subject elements or groups of elements may occur. As additional data is gathered due to Training Module use over time, the increase may provide the necessary data volume and variation from which possible useful processes, including sampling and comparing data for automatic classification, speech recognition software supported automatic classification, generative design of new examples, tracking and scoring student progress, and general performance analysis, time keeping, and scoring of all users may occur. It is for these possible uses, and likely others not yet considered, all data should be captured as the Training Module is utilized over time. (step 316 of FIG. 3)

Depending on the extent of useable elements of data captured and implemented in the classification of a workpiece of questionable configuration, additional classification input may be made manually by the modeler such as plumbing fixture type, depth of available underfloor working space, ceiling space height, and relative tie-in elevation and distance, etc. For this manual process, a sub-window opens which presents a dropdown, radio button, or check box style option choice interface, along with specific value input, for this input of properties of the assembly or group of elements and pertinent conditions associated with the assembly or group of elements of concern. (step 316 of FIG. 3)

After the configuration related information input is completed the modeler clicks “next”. A link or import function is thus called which activates a presentation window in which a selection of the examples from the library folder having a classification label which matches the input classification. The examples shown the modeler are pertinent plumbing system configuration examples which are related to the questionable configuration. (Presentation Window Examples 318 of FIG. 3)

The modeler ponders the configurations presented and based on careful consideration of the situation, may choose the best option to use as a guide. Alternatively, he may delay choosing until further information is gathered, by selecting the “Tutorial Option” button 208 (FIG. 2C) on the presentation window which will call for more related support information to assist in understanding of the proper configuration of the plumbing system in the present situation. For example, the modeler may not have the experience and knowledge needed to create a plumbing system to handle the drainage and venting of a bathroom including a Water Closet, Lavatory, Urinal, and Floor Drain. The possibilities of pipe and fittings configuration is constrained, not only by the required sizes of main and branch piping, but also by the available depth for slope, proximity of building structural members, walls, and depth of downstream connection points, among other things. Predominant plumbing codes necessarily treat many aspects of all these things. The myriad code issues must be considered separately and in combination when figuring out the best possible layout which is, by definition, that which a journeyworker would do.

Based on the information and learning, the best example option is selected. Upon selection, a best example image is placed near the working model area of concern by, for example, a mouse click and further manipulation to achieve desired placement on the working model canvas. Programmatic steps for an example routine are described below with reference to FIG. 3 and FIG. 7B.

In the example system, provision is made for transferring the selected best example option into the actual model file (e.g., dropped into the canvas of the model file). However, useful journey-worker training could be accomplished without facilitating the direct transfer of the selected best example into the canvas of the BIM application.

Data 336 related to the chosen example and the advanced tab docs obtained and reviewed, including time spent in review and areas of review, is transmitted to Data Storage 120 of FIG. 1 through Use Data Interfaces 118.

The originally placed “best attempt” configuration is compared with the chosen example. Coordination with other building elements is also considered. If the “best attempt” work is acceptable, it is left in place. If not acceptable, the modeler deletes the original content and places new content once again in a configuration which more closely matches the example. The “best attempt”, as originally created or modified, or a wholly new configuration, more closely meets the code and practices standards to which the example and other information have helped illustrate. Depending on the complexity of the specific area of the craft, this may be the only time the modeler needs to fully learn and understand the standards for this type of instance, or it may be but one of several tries before the modeler achieves “virtual journeyworker” knowledge of that type of system configuration.

After completing any required rework, the modeler is again prompted to create an assembly of the modeled configuration, or otherwise define the configuration by selecting the individual elements in the group of elements of the reworked configuration. The data related to the rework assembly is also sent to USE DATA INTERFACES 118 and DATA STORAGE 120 of FIG. 1, as in the earlier step for purposes of data comparison and study for future use and development in supporting regular or even “artificial intelligence” (AI) processes. (FIG. 3—332-334).

Finally, in step 334 of FIG. 3, when the sequence is terminated the original or reworked model assembly is automatically disassembled and the example image is automatically deleted from the modeling canvas, resulting in a model clear of any elements associated with the Training Module process. The modeler continues with the project. (FIGS. 3—334)

Referring back to the Training Module initiation 302, if “BIM-App Tutorials” is chosen, the modeler is further prompted to choose “Craft-Type” in step 344 of FIG. 3. The sequences and tutorial results of this prompt are related to functionality and best practices of the BIM app itself as directly related to functionalities useful on the specific craft type being modeled. (FIGS. 2A, 2D, 3, 8A, 8B)

For example, the modeler may be interested in plumbing systems of graded pipe and fittings of Fabrication™ content and how to best manipulate the controls for placing these elements in the model. The different types of content for plumbing, native or Fabrication™ may have unique behaviors in comparison with other building modeling content. Special or unique content behavior may present the need for training attention by either the novice BIM App user, or an advanced BIM App user who is newly working with unfamiliar craft content. In either case, the modeler could review the option tree leading to the topic and choose from the content library presented, or in the case of an AI supported system, at least one option may be automatically prompted for choice in further defining the modeler learning path. (FIG. 3—344)

Various videos, examples, product brochures, notes, expert comments, augmented and virtual reality presentations, and other educational content files related to the virtual or real-world situation at hand would be available by manually activated direct access to whatever related information the modeler may determine could be helpful. Or in the case of some type of AI supported search based on data previously gained in the immediate user session past along with historical and other widespread sources added to the overall data store, applicable possible choices of products and information may be presented to the modeler. For example, the plumbing system modeler may wish to see what types of “water saver” fixtures are available and how these might be useful given the geographic area of the project. In this case the modeler could directly access the code regarding low-water consumption for the area as well as manufacturer brochures which would satisfy the geographically and jurisdictionally germane building or plumbing code.

When the modeler understands enough to continue effective modeling in the present situation, the “BIM App Tutorials” training aspect of the present invention is terminated from the UI yet remains available to reopen at any time. The record from the “BIM App Tutorials” use is captured and saved for user specific as well as a global or multi-user scope bases. In either case, if employed, the useful recorded data will support better “BIM App Tutorials” training as well as increasing efficacy of the present invention's training protocols for human programmed, or AI supported data analysis and aggregation.

### Data Capture and Store

Although not a requirement for the fundamental system and method, all data related to this may be captured and stored, including but not limited to; raw, binary, unstructured, semi-structured, and structured data (such as the pairings of assemblies from modeler original and chosen example); as part of a common data environment (CDE); durations of sequences; time; websites; media; documents; links; pre-processed data for use by third-party AI-based training or search systems, supervised machine learning, semantic enrichment, graph representation, or other emerging technologies, journals of BIM App sessions and sub journals of the Training Module processes. See, for example, block 506 of FIG. 5 and data storage 120 of FIG. 1.

The saved data from both Training Module “front end” or Admin “backend” use may be useful in the future in many ways. Emerging AI search and process functionality, drawing from stored data of elements and assemblies or configurations of elements, whether created on the front or back ends at any previous time by at least one modeler or administrator, may automatically populate at least one aspect or increment of the classification string for the subject assembly or configuration of elements. AI functionality may also be utilized to assist in creation of more directly useful things such as basic element geometry within the purview of the BIM application. Generative design functionality, an aspect of Revit™ and considered a subset of AI functionality, may be utilized to create various assemblies or configurations based upon the data captured, as well as appropriate additional administrative input data, of similar assemblies or configurations created on both the front and back ends over time and saved in the data warehouse or data lake. Example methods of saving data via the front end of the system are described above.

### The Back End

The system and method will entail administration, curating, and other back-end effort and structure of two categories; “Journeywork” and “BIM App” as previously described and corresponding to the control buttons 202 and 204 (FIG. 2A), respectively, on the initial UI.

For the plumbing “Journeywork” option library, BIM App files such as Revit™.rvt files, are created with various configurations of elements such as pipe and fittings used in a given type of system and situation. For each like-kind variation, these are the “primary file”. Separately these primary files are stored in sub-folders which are then grouped into a single classified folder held in Example Folders (112). A copy of each primary file is created within the sub-folder and the elements of the copy are joined into a single element such as an “assembly”. Next, an image file is created of the primary configuration, for example by employing Navisworks Manage™ from which an .nwd file may be created. This .nwd file is then inserted into an empty third .rvt file within the sub-folder. Finally, at least a 3D .pdf of the primary file element configuration is created. Other .pdfs such as plan view and section views also may be created. The .pdfs may include links or notes which contribute to the overall teaching matter available. During front end use a group of 3D .pdfs are presented to the Training Module app modeler. See, for example, Presentation Window Examples 318 of FIG. 3 and Best Option Choice 206 of FIG. 7B.

The separately classified sub-folders are stored in a classified folder which is stored in the Example Folders 112. If programmatic classification of the files and/or sub-folders and/or folders is not possible due to lack of stored data or lack of operating system programmed capacity, fully manual classification of all can suffice. As data is gathered over time the increase may provide the necessary substance from which programmatic classification, in whole or in part, may occur. Accordingly, as the system and method is developed programmatic classification capacity may be attained to utilize the available data.

After the modeler chooses the best example for the particular situation, the following programmatic sequence summarized in FIG. 7B begins. In a first step (1), sub-folder BIM App file with an image of a chosen model is opened. In a second step (2), the image is selected in a file. In a third step (3), the image is copied to the clipboard. In a fourth step (4), the working model is activated. In a fifth step (5), the image from the clipboard is pasted at mouse point location. In a sixth step (6), the new project (with Image) is closed/no save.

When the modeler is focused on an element and has unresolved concern, more information may be desired. In such a case, a “best effort” modeling effort is made. Accordingly, once the Training Module sequence has reached the state of example presentations, the “Tutorial Option” button 208 of FIG. 2C appears in the presentation window. When clicked, the tutorial screen appears providing access to the deeper learning dive.

A user-choice opportunity is presented of general and targeted information pertinent to the classification of the examples first shown. For example, if a plumbing drain, waste, and vent (aka: DWV) system, required to be built in a deep ceiling or ground situation as opposed to a shallow situation, is the classified category of examples called, options presented in the tutorial would include things pertinent to that category.

The Admin “back end” role in tutorial development and classification may include manual, semi-manual, and programmatic aspects in the curating and classifying processes. There are many forms and sources for useful content which may be accessed publicly online, through 3rd Party providers, or saved in the library. Some of these may include: applicable plumbing code excerpts, pictures of real-world plumbing systems, detail drawings from previous projects, videos with journeyworker narratives, typical specification portions, product brochures, and many other useful resources such as 3D Pics, lidar data, VR/AR point cloud type experiences, Immersive Technology, schematic drawings, PI&D, “notes, suggestions and cautions”, NLP search and support, etc.

The “BIM App” button 204 of FIG. 2A is designed to trigger craft-specific aspects of the BIM App operation as previously mentioned. For example, in modeling plumbing with .itm content some BIM App operation qualities might be unique or obscure. During admin development of the Tutorial Resources 114, various scenarios of these tricky areas, and how to handle them, can be set up and isolated in short training screencasts and other support documents.

### Alternative Proprietary-Related Services

All stored files, whether example or tutorial type, can be controlled with user access permissions. This creates a means whereby subscribed organizations with proprietary training information can use their private information and insure it is only accessible to the modeler within their organization. For example, if the training materials are being hosted on a cloud service, some of the training materials can be accessible to all users, and other training materials, data, and so on can be limited to one or more particular users (e.g., all employees of a particular company client of the cloud provider). In addition, data capture (e.g., best option selections, etc.) can be used to update/develop the private database of the particular user from which the data came.

As disclosed, “materials” is a category which is included in possible tutorial content libraries. Through this aspect of the Training Module, a manufacturer or distributor of any building material, or other factory produced item, may provide information about their product to potential customers.

The present invention provides the unassisted modeler examples of correctly modeled increments, pertinent building codes, and important considerations regarding the work and jobsite circumstances among other things. The invention is a system and method of virtual construction craft training and the associated BIM App operation training tailored around the specific construction craft. It is a means of efficiently training a person as a journeyworker-in-part, a skillset which includes knowledge of the creation of actual journeywork yet without the requirement to learn the many techniques of hands one work, tool use, and jobsite safety protocols as is within the skill set of an actual journeyworker. This new category of the workforce may be called a “Virtual Journeyworker”.

Steps of the overall operation are summarized as follows. First, the Training Module is activated. Second, the modeler logs in or the Training Module is terminated. Third, the modeler chooses “JOURNEYWORK” or “BIM APP”. Fourth, if the “JOURNEYWORK” modeler chooses “CRAFT-TYPE” and “PROJECT”, the correlated steps sequence begins. If the “BIM APP” is chosen, the modeler further chooses “CRAFT-TYPE” and the correlated steps sequence begins. Fifth, the option to terminate the Training Module is clicked in the log-in window.

The steps of the administrator are summarized as follows. First, a library of classified model portion examples is established, maintained, and developed (multiple file formats). Second, a library of tutorial content is established, maintained, and developed. Third, a user-database, billing system, and log-in system is established and maintained. Fourth, third party backend interactive support system connections are established and maintained. Fifth, a user helpdesk/troubleshooter is established, maintained, and developed. Sixth, data saving systems are maintained.

Steps of full-version “Journeywork” option (data save and tutorial content) are summarized as follows. First, a modeler creates a new model portion. Second, the modeler activates the Training Module. Third, the modeler actions save begin. (i.e. isolated journal of the Training Module session begin). Fourth, the modeler is prompt to convert the new model portion to a whole assembly element consisting of the discrete parts. Fifth, whole assembly data and the classification data thereof are saved in the data lake. Sixth, classification of assembly manually or a combination of manual and automatic occurs. Seventh, corresponding classified library examples are called. Eighth, best option 3D .pdf out of a group of examples is chosen by the modeler and expands to fill the selection window. Ninth, media related to matching examples are made available to call (optional/multi). Tenth, an image of the best option is inserted on the working model canvas for side-to-side comparison. (different than pdf in step 7, this is a coordination model insert in Revit). Eleventh, new model portion assembly is automatically disassembled. (last assembly created from journal). Twelfth, the modeler modifies (or leaves intact after checking) the new model portion based on the image. Thirteenth, the modeler is prompt to convert the final model portion to a whole second assembly element consisting of the discrete parts of the modified configuration. Fourteenth, the whole second assembly data and the classification data thereof are saved in data lake. Fifteenth, the modeler actions save end (i.e. isolated journal of the Training Module session end—at which point the journal is saved in data lake) and the Training Module log-in window is presented (may be minimized or if closed, terminates the Training Module).

The steps of bare bones “craft” option (no data saving, no tutorial content) is summarized as follows. First, the modeler creates a new model portion. Second, classification of assembly is done manually. Third, corresponding classified library examples are called. Fourth, the best option .pdf out of a group of examples is chosen by the modeler and expands to fill the selection window. Fifth, the image of the best option is inserted on the working model canvas for a side-to-side comparison (different image than pdf in 4, this is a Navisworks coordination model insert in Revit). Sixth, the modeler modifies (or leaves intact after checking) the new model portion based on the image. Seventh, the modeler modifies (or leaves intact after checking) the new model portion based on the new example .rfa configuration, or may use the pasted version as the new modeled work, deleting, in whole or in part, the best attempt version. Eighth, Finishes/exit.

The steps of “BIM APP” sub-option “CRAFT-TYPE RELATED” are summarized as follows. First, the modeler clicks on “BIM App”. Second, the modeler is presented with basic BIM APP CRAFT-RELATED training options. Third, the modeler chooses option and reviews. Fourth, the modeler closes the option presentation. Fifth, the BIM app training option window returns. Sixth, the modeler repeats the sequence or closes the training window. Seventh, the log-in window is presented.

The description of particular embodiments of the present invention is now complete. Many of the described features may be substituted, altered or omitted without departing from the scope of the invention. For example, alternate number of processors, may be substituted for the Training Module Processor. As another example, the example systems described may be integral to a building information modeling application or may be carried out in third party Add-on application. As yet another example, “best options” might depend on environmental impact (e.g., carbon footprint) of a particular component/assembly as indicated, for example, by the metadata associated with the component/assembly. The carbon footprint can relate to the manufacture of the components (e.g., toilet, pipe, carpet, countertop, partition, doors, windows, and so on), required transportation of the components to the work site, efficiency of the installed components, disposal of the components, and so on). These and other deviations from the particular embodiments shown will be apparent to those skilled in the art, particularly in view of the foregoing disclosure.

We claim:

1. A method for training a user of a construction modeling system, said method comprising:
presenting a model file to said user;
receiving a request for assistance from said user, said request including information related to a particular portion of a model file of said construction modeling system and information identifying a particular craft;
processing said request to identify training materials corresponding to said request;
presenting indicia of said identified training materials to said user;
receiving selection input from said user, said selection input indicating the selection of at least one of said training materials as a selected training material;
retrieving said selected training material;
presenting said retrieved training material to said user;
facilitating the modification of said model file by said user based on said presented training material.

2. The method of claim 1, wherein said training materials include an image of at least one assembly of components corresponding to said particular craft.

3. The method of claim 1, wherein said information related to said particular portion of said model file includes:
an assembly created by said user and corresponding to said particular craft; and
a second assembly of components corresponding to at least one other craft different than said particular craft, said assembly and said second assembly being in a same portion of said model file, whereby said second assembly constrains a configuration of said assembly.

4. The method of claim 3, wherein said training materials include information corresponding to at least one pre-approved assembly suitable for use in combination with said second assembly.

5. The method of claim 4, wherein said at least one pre-approved assembly is representative of an actual installed assembly from a prior construction project.

6. The method of claim 1, wherein said training materials include an instructional video related to field installation of an assembly corresponding to said particular craft.

7. The method of claim 1, wherein receiving said request for assistance from said user includes presenting said user with a choice between training in the use of said modeling system and virtual training in said particular craft.

8. The method of claim 1, wherein said particular craft includes one of carpentry, plumbing, electrical, masonry, and heating, ventilation, and air conditioning.

9. The method of claim 1, wherein said training materials include information relating to an environmental impact of one or more components represented within said model file.

10. The method of claim 1, further comprising storing a record indicative of said user's selection of said selected training material.

11. The method of claim 1, further comprising storing an assembly of said modified model file as a new training material.

12. The method of claim 1, wherein said information related to a particular portion of a model file includes:
said user's selection of said particular portion of said model file; and
other information manually entered by said user.

13. The method of claim 1, wherein:
said training materials include a plurality of pre-approved assemblies, each of said pre-approved assemblies being stored in association with a dimension value and a material type indicator;
said information related to said particular portion of said model file includes an assembly created and selected by said user in said model file and contained within a bounding box; and
processing said request to identify said training materials corresponding to said request includes determining a material type of said selected assembly, determining at least one dimension of said bounding box, and searching said plurality of pre-approved assemblies to identify particular ones of said pre-approved assemblies with a material type indicator that corresponds to said material type of said selected assembly and with a dimension value that is within a predetermined range of a dimension of said bounding box.

14. The method of claim 13, wherein:
each of said pre-approved assemblies are stored in association with a volume value; and
processing said request to identify said training materials corresponding to said request includes determining a volume of said bounding box and searching said plurality of pre-approved assemblies to identify particular ones of said pre-approved assemblies with a volume value that is within a predetermined range of said volume of said bounding box.

15. The method of claim 1, wherein said processing of said request to identify training materials corresponding to said request includes:
determining a geographical location corresponding to a construction site; and
identifying said training materials based at least in part on said geographical location.

16. A system for training a user of a construction modeling system, said system comprising:
a hardware processor configured to execute code, said code including a set of predefined instructions that cause said hardware processor to perform associated operations; and
memory for storing data and said code, said data and said code including
a modeling service including a first subset of said set of predefined instructions configured to present a model file to a user and to facilitate modification of said model file by said user; and
a training service including a second subset of said set of predefined instructions configured to
receive a request for assistance from said user, said request including information related to a particular portion of a model file and information identifying a particular craft,
to process said request to identify training materials corresponding to said request,
to present indicia of said identified training materials to said user,
to receive selection input from said user, said selection input indicating the selection of at least one of said training materials as a selected training material;
to retrieve said selected training material, and
to present said retrieved training material to said user; and
whereby said modeling service facilitates modification of said model file by said user based on said presented training material.

17. The system of claim 16, wherein said training materials include an image of at least one assembly of components corresponding to said particular craft.

18. The system of claim 16, wherein said information related to said particular portion of said model file includes:
an assembly created by said user and corresponding to said particular craft; and
a second assembly of components corresponding to at least one other craft different than said particular craft, said assembly and said second assembly being in a same portion of said model file, whereby said second assembly constrains a configuration of said assembly.

19. The system of claim 18, wherein said training materials include information corresponding to at least one pre-approved assembly suitable for use in combination with said second assembly.

20. The system of claim 19, wherein said at least one pre-approved assembly is representative of an actual installed assembly from a prior construction project.

21. The system of claim 16, wherein said training materials include an instructional video related to field installation of an assembly corresponding to said particular craft.

22. The system of claim 16, wherein receiving said request for assistance from said user includes presenting said user with a choice between training in the use of said modeling system and virtual training in said particular craft.

23. The system of claim 16, wherein said particular craft includes one of carpentry, plumbing, electrical, masonry, and heating, ventilation, and air conditioning.

24. The system of claim 16, wherein said training materials include information relating to an environmental impact of one or more components represented within said model file.

25. The system of claim 16, wherein said data includes a record indicative of said user's selection of said selected training material.

26. The system of claim 16, wherein said training service additionally includes a third subset of said set of predefined instructions configured to store data indicative of an assembly of said modified model file as a new training material.

27. The system of claim 16, wherein said information related to a particular portion of a model file includes:
said user's selection of said particular portion of said model file; and
other information manually entered by said user.

28. The system of claim 16, wherein:
said training materials include a plurality of pre-approved assemblies, each of said pre-approved assemblies being stored in association with a dimension value and a material type indicator;
said information related to said particular portion of said model file includes an assembly created and selected by said user in said model file and contained within a bounding box; and
processing said request to identify said training materials corresponding to said request includes determining a material type of said selected assembly, determining at least one dimension of said bounding box, and searching said plurality of pre-approved assemblies to identify particular ones of said pre-approved assemblies with a material type indicator that corresponds to said material type of said selected assembly and with a dimension value that is within a predetermined range of a dimension of said bounding box.

29. The system of claim 28, wherein:
each of said pre-approved assemblies are stored in association with a volume value; and
processing said request to identify said training materials corresponding to said request includes determining a volume of said bounding box and searching said plurality of pre-approved assemblies to identify particular ones of said pre-approved assemblies with a volume value that is within a predetermined range of said volume of said bounding box.

30. The method of claim 16, wherein said processing of said request to identify training materials corresponding to said request includes:
determining a geographical location corresponding to a construction site; and
identifying said training materials based at least in part on said geographical location.
